(19) United States
(12) Patent Application Publication
(10) Pub. No.: US 2026/0269806 A1
(43) Pub. Date: Sep. 10, 2026

(54) Resonator Device

(71) Applicant: SEIKO EPSON CORPORATION, Tokyo (JP)

(72) Inventors: Junichi TAKEUCHI, Chino (JP); Koji HOSAKA, Minamiminowa (JP); Yukihiro HASHI, Shiojiri (JP); Takuya OWAKI, Shimosuwa (JP); Ryo ICHIKAWA, Minamiminowa (JP)

(21) Appl. No.: 19/555,045

(22) Filed: Mar. 3, 2026

(30) Foreign Application Priority Data
Mar. 4, 2025 (JP) 2025-033538

(51) Int. Cl. H03H 9/05; H03H 9/10; H03H 9/19

(52) U.S. Cl. CPC H03H 9/0538; H03H 9/10; H03H 9/19

(57) ABSTRACT

A resonator device includes a semiconductor substrate having a first surface and a second surface being opposite to each other, a resonator that is bonded to the first surface and includes a resonator element and a container housing the resonator element, an integrated circuit portion that is formed on the second surface and includes an oscillation circuit electrically connected to the resonator element, and mounting terminals connected to the integrated circuit portion.

The present application is based on, and claims priority from JP Application Serial Number 2025-033538, filed Mar. 4, 2025, the disclosure of which is hereby incorporated by reference herein in its entirety.

### BACKGROUND

### 1. Technical Field

The present disclosure relates to a resonator device.

### 2. Related Art

A resonator device in which a resonator element is housed in a package is known.

For example, JP-A-2015-89095 describes a surface mounting type low-profile oscillator in which a resonator unit and an IC chip unit are integrated. The IC chip unit which is a bare chip has, on a main surface thereof, an integrated circuit portion (IC circuit pattern) in which an oscillator configuration circuit including a circuit forming an oscillation circuit together with a resonator of the resonator unit is integrated, and an IC terminal including a plurality of IC electrode terminals and two quartz crystal connection terminals connected to external terminals of the resonator unit. A plurality of mounting terminals are provided on a back surface (a surface opposite to the main surface, a mounting surface) of the IC chip unit, and each of the IC electrode terminals on the main surface is electrically connected to a corresponding one of the mounting terminals on the back surface by a corresponding one of electrode columns (also referred to as through electrodes) provided in a corresponding one of via holes passing through a silicon plate of the bare chip in a thickness direction.

However, in JP-A-2015-89095, since the integrated circuit portion is electrically connected to the mounting terminals via the through electrodes, the jitter characteristics may be deteriorated due to parasitic components of the through electrodes.

### SUMMARY

According to an aspect of the present disclosure, there is provided a resonator device including a semiconductor substrate having a first surface and a second surface being opposite to each other, a resonator that is bonded to the first surface and includes a resonator element and a container housing the resonator element, an integrated circuit portion that is formed on the second surface and includes an oscillation circuit electrically connected to the resonator element, and mounting terminals connected to the integrated circuit portion.

### BRIEF DESCRIPTION OF THE DRAWINGS

FIG. 1 is a sectional view schematically illustrating a resonator device according to the present embodiment.

FIG. 2 is a sectional view schematically illustrating a resonator of the resonator device according to the present embodiment.

FIG. 3 is a plan view schematically illustrating the resonator of the resonator device according to the present embodiment.

FIG. 4 is a sectional view schematically illustrating a manufacturing process of the resonator device according to the present embodiment.

FIG. 5 is a sectional view schematically illustrating a manufacturing process of the resonator device according to the present embodiment.

FIG. 6 is a sectional view schematically illustrating a manufacturing process of the resonator device according to the present embodiment.

FIG. 7 is a sectional view schematically illustrating a manufacturing process of the resonator device according to the present embodiment.

FIG. 8 is a perspective view schematically illustrating a manufacturing process of the resonator device according to the present embodiment.

FIG. 9 is a sectional view schematically illustrating a resonator device according to a first modification of the present embodiment.

FIG. 10 is a sectional view schematically illustrating a resonator of a resonator device according to a second modification of the present embodiment.

FIG. 11 is a plan view schematically illustrating the resonator of the resonator device according to the second modification of the present embodiment.

FIG. 12 is a sectional view schematically illustrating the resonator of the resonator device according to the second modification of the present embodiment.

### DESCRIPTION OF EMBODIMENTS

Hereinafter, a preferred embodiment of the present disclosure will be described in detail with reference to the drawings. Further, the embodiment to be described below does not inappropriately limit the contents of the present disclosure described in the claims. In addition, not all of the configurations that will be described below are necessarily essential requirements of the present disclosure.

### 1. Resonator Device

### 1.1. Overall Configuration

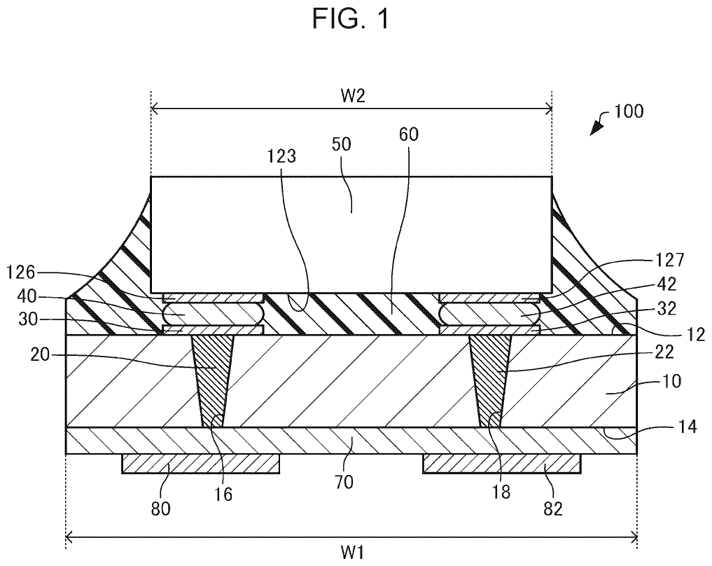

First, a resonator device according to the present embodiment will be described with reference to the drawings. FIG. 1 is a sectional view schematically illustrating a resonator device 100 according to the present embodiment.

As illustrated in FIG. 1, the resonator device 100 includes, for example, a semiconductor substrate 10, a first through electrode 20, a second through electrode 22, a first connection terminal 30, a second connection terminal 32, a first bonding member 40, a second bonding member 42, a resonator 50, a resin material 60, an integrated circuit portion 70, a first mounting terminal 80, and a second mounting terminal 82.

The semiconductor substrate 10 is, for example, a silicon substrate. The semiconductor substrate 10 has a first surface 12 and a second surface 14 being opposite to each other. For example, the first surface 12 and the second surface 14 are parallel to each other. In the illustrated example, the first surface 12 is an upper surface of the semiconductor substrate 10. The second surface 14 is a lower surface of the semiconductor substrate 10.

A first through hole 16 and a second through hole 18 are formed in the semiconductor substrate 10. The through holes 16 and 18 are spaced apart from each other. The through holes 16 and 18 pass through the semiconductor substrate 10 from the first surface 12 to the second surface 14. Each of the areas of the openings of the through holes 16 and 18 in the first surface 12 is, for example, larger than a corresponding one of the areas of the openings of the through holes 16 and 18 in the second surface 14.

The first through electrode 20 is provided in the first through hole 16. The second through electrode 22 is provided in the second through hole 18. The through electrodes 20 and 22 pass through the semiconductor substrate 10. The material of the through electrodes 20 and 22 is, for example, copper, gold, aluminum, or the like.

The first connection terminal 30 and the second connection terminal 32 are provided on the first surface 12 of the semiconductor substrate 10. The connection terminals 30 and 32 are spaced apart from each other. The first through electrode 20 electrically connects the integrated circuit portion 70 to the first connection terminal 30. The second through electrode 22 electrically connects the integrated circuit portion 70 to the second connection terminal 32. The connection terminals 30 and 32 are formed by laminating a coating of nickel, gold, silver, copper, or the like on a base layer of chromium, tungsten, or the like.

The first bonding member 40 is provided on the first connection terminal 30. The first bonding member 40 is provided between the first connection terminal 30 and the resonator 50. The second bonding member 42 is provided on the second connection terminal 32. The second bonding member 42 is provided between the second connection terminal 32 and the resonator 50. As the bonding members 40 and 42, for example, solder is used. The bonding members 40 and 42 are not limited to solder, and may be a conductive resin, a bump, or the like.

The resonator 50 is bonded to the first surface 12 of the semiconductor substrate 10. In the illustrated example, the resonator 50 is bonded to the first surface 12 via the bonding member 40 and the connection terminal 30. The resonator 50 is mounted on the semiconductor substrate 10. In other words, the resonator 50 is pasted to the semiconductor substrate 10. In plan view, the area of the semiconductor substrate 10 is, for example, larger than the area of the resonator 50. For example, a width W1 of the semiconductor substrate 10 is larger than a width W2 of the resonator 50. In plan view, the area of the resonator device 100 is, for example, the same as the area of the semiconductor substrate 10. The configuration of the resonator 50 will be described later.

The resin material 60 is provided on the first surface 12 of the semiconductor substrate 10. In plan view, the resin material 60 surrounds the resonator 50. In the illustrated example, the resin material 60 is in contact with side surfaces of the resonator 50. A space between the semiconductor substrate 10 and the resonator 50 is filled with the resin material 60. The resin material 60 is in contact with the connection terminals 30 and 32 and the bonding members 40 and 42. The resin material 60 is, for example, an underfill material. The material of the resin material 60 is, for example, polyimide, polyurethane, polyester, a phenol resin, a urea resin, a melamine resin, or a silicone resin.

The integrated circuit portion 70 is formed on the second surface 14 of the semiconductor substrate 10. The integrated circuit portion 70 is formed by fabricating an integrated circuit (IC) on the second surface 14 of the semiconductor substrate 10 by a semiconductor process. The integrated circuit portion 70 includes, for example, a transistor, a resistor, and a capacitor. The integrated circuit portion 70 includes an oscillation circuit for oscillating a resonator element of the resonator 50. The oscillation circuit is electrically connected to the resonator element of the resonator 50 via the first through electrode 20, the first connection terminal 30, and the first bonding member 40. Further, the oscillation circuit is electrically connected to the resonator element of the resonator 50 via the second through electrode 22, the second connection terminal 32, and the second bonding member 42.

The first mounting terminal 80 and the second mounting terminal 82 are connected to the integrated circuit portion 70. The mounting terminals 80 and 82 are directly connected to the integrated circuit portion 70 without using through electrodes. The mounting terminals 80 and 82 are in contact with the integrated circuit portion 70. In the illustrated example, the mounting terminals 80 and 82 are provided under the integrated circuit portion 70. For example, the first mounting terminal 80 overlaps the first through electrode 20 in plan view. For example, the second mounting terminal 82 overlaps the second through electrode 22 in plan view. The mounting terminals 80 and 82 may each include a metal layer and a plating layer provided on a surface of the metal layer. The metal layer is, for example, a copper layer. As the plating layer, for example, a layer obtained by laminating a nickel layer, a palladium layer, and a gold layer in this order from the metal layer side is used. The plating layer can suppress oxidation of the metal layer. When the mounting terminals 80 and 82 are bonded to an external member (not illustrated), the resonator device 100 is mounted on the external member.

Although not illustrated, a protective layer for protecting the integrated circuit portion 70 may be provided between the integrated circuit portion 70 and the mounting terminals 80 and 82. Each of the mounting terminals 80 and 82 may be electrically connected to the integrated circuit portion 70 via a corresponding one of contact holes formed in the protective layer. The protective layer is, for example, a polyimide layer.

### 1.2. Resonator

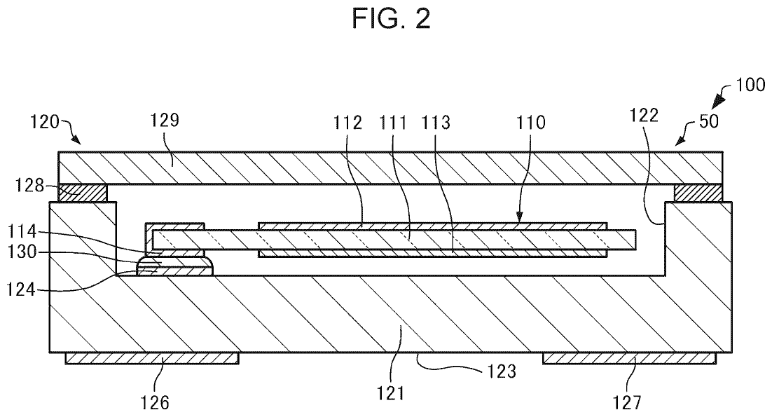

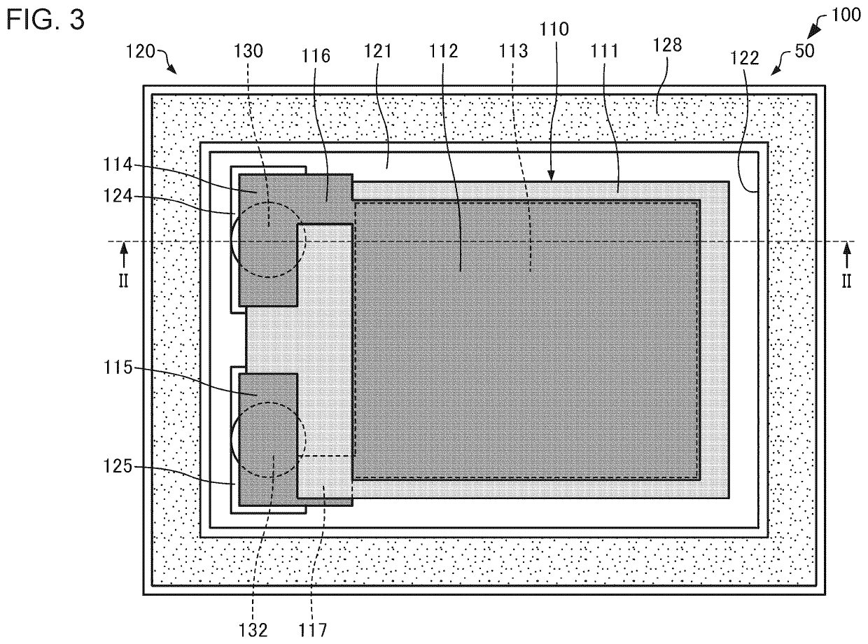

FIG. 2 is a sectional view schematically illustrating the resonator 50. FIG. 3 is a plan view schematically illustrating the resonator 50. FIG. 2 is a sectional view taken along line II-II in FIG. 3.

As illustrated in FIGS. 2 and 3, the resonator 50 includes a resonator element 110, a container 120, a first metal bump 130, and a second metal bump 132. For convenience, a lid 129 of the container 120 is not illustrated in FIG. 3.

The resonator element 110 includes, for example, a vibrating substrate 111, a first excitation electrode 112, a second excitation electrode 113, a first terminal 114, a second terminal 115, first wiring 116, and second wiring 117.

The vibrating substrate 111 is, for example, an AT cut quartz crystal substrate. Since the AT cut quartz crystal substrate has cubic frequency-temperature characteristics, it has excellent temperature characteristics. The vibrating substrate 111 vibrates with thickness-shear vibration as a main vibration. The “thickness-shear vibration” is a vibration in which a displacement direction of the quartz crystal substrate is parallel to the main surface of the quartz crystal substrate and a wave propagation direction is a thickness direction of the quartz crystal substrate.

The first excitation electrode 112 is provided on one main surface of the vibrating substrate 111. In the illustrated example, the first excitation electrode 112 is provided on an upper surface (front surface) of the vibrating substrate 111. The second excitation electrode 113 is provided on the other main surface of the vibrating substrate 111. In the illustrated example, the second excitation electrode 113 is provided on a lower surface (rear surface) of the vibrating substrate 111. The vibrating substrate 111 is clipped by the excitation electrodes 112 and 113. In plan view, the excitation electrodes 112 and 113 each have, for example, a rectangular shape. The excitation electrodes 112 and 113 are electrodes that apply a voltage to the vibrating substrate 111. The vibrating substrate 111 performs the thickness-shear vibration when the voltage is applied by the excitation electrodes 112 and 113.

The first terminal 114 is electrically connected to the first excitation electrode 112 via the first wiring 116. For example, the first terminal 114 is provided on the front and rear surfaces and side surfaces of the vibrating substrate 111. The second terminal 115 is electrically connected to the second excitation electrode 113 via the second wiring 117. For example, the second terminal 115 is provided on the front and rear surfaces and the side surfaces of the vibrating substrate 111. The excitation electrodes 112 and 113, the terminals 114 and 115, and two pieces of wiring 116 and 117 are each formed by, for example, laminating a chromium layer and a gold layer in this order from the vibrating substrate 111 side.

The configuration of the resonator element 110 is not limited to the above-described configuration. For example, the resonator element 110 may be a mesa type in which a resonance region interposed between the excitation electrodes 112 and 113 protrudes from the periphery thereof. Alternatively, conversely, the resonator element 110 may be an inverted mesa type in which the resonance region is recessed from the periphery thereof. In addition, bevel processing for grinding the periphery of the vibrating substrate 111 or convex processing for forming the upper surface and the lower surface as convex curved surfaces may be performed.

In addition, the vibrating substrate 111 is not limited to one that performs the thickness-shear vibration. The vibrating substrate 111 may be, for example, a substrate in which a plurality of vibrating arms perform flexural vibration in an in-plane direction as in a tuning fork type resonator element. That is, the vibrating substrate 111 is not limited to the AT cut quartz crystal substrate, and may be a quartz crystal substrate other than the AT cut quartz crystal substrate, for example, an X cut quartz crystal substrate, a Y cut quartz crystal substrate, a Z cut quartz crystal substrate, a BT cut quartz crystal substrate, an SC cut quartz crystal substrate, or an ST cut quartz crystal substrate.

In addition, the material of the vibrating substrate 111 is not limited to quartz crystal. The vibrating substrate 111 may be formed of, for example, a piezoelectric single crystal such as lithium niobate, lithium tantalate, lithium tetraborate, langasite crystal, potassium niobate, or gallium phosphate, or may be formed of a piezoelectric single crystal other than these. Further, the resonator element 110 is not limited to a piezoelectric driving type, and may be an electrostatic driving type using an electrostatic force.

The container 120 is a package that houses the resonator element 110. The container 120 includes, for example, a base 121, a first internal terminal 124, a second internal terminal 125, a first external terminal 126, a second external terminal 127, a seam ring 128, and the lid 129.

The base 121 is made of, for example, ceramic such as alumina, silicon, or the like. The base 121 has a recessed portion 122 formed in an upper surface thereof, the recessed portion 122 having an opening. The resonator element 110 is housed in a space formed by the recessed portion 122. The space of the recessed portion 122 is airtight and in a reduced pressure state, preferably in a near-vacuum state. Thus, the viscous resistance is reduced, and the resonance characteristics of the resonator element 110 are improved. The space of the recessed portion 122 may be a sealed atmosphere of an inert gas such as nitrogen or argon.

The base 121 has an outer shell surface 123 that constitutes an outer shell of the container 120. The outer shell surface 123 is a surface on which the external terminals 126 and 127 are provided. For example, the outer shell surface 123 faces the first surface 12 of the semiconductor substrate 10. In the illustrated example, the outer shell surface 123 is an outer bottom surface of the container 120. As illustrated in FIG. 1, a space between the first surface 12 of the semiconductor substrate 10 and the outer shell surface 123 of the container 120 is filled with the resin material 60.

As illustrated in FIGS. 2 and 3, the first internal terminal 124 and the second internal terminal 125 are provided on the base 121. The internal terminals 124 and 125 are provided inside the container 120. The internal terminals 124 and 125 are spaced apart from each other.

The first external terminal 126 and the second external terminal 127 are provided on the outer shell surface 123 of the container 120. The external terminals 126 and 127 are spaced apart from each other. The first external terminal 126 is electrically connected to the first internal terminal 124 via a first conductive member (not illustrated) formed in the base 121. The first external terminal 126 is electrically connected to the resonator element 110 via the first internal terminal 124 and the first metal bump 130. The first external terminal 126 and the first connection terminal 30 are connected to each other via the first bonding member 40.

The second external terminal 127 is electrically connected to the second internal terminal 125 via a second conductive member (not illustrated) formed in the base 121. The second external terminal 127 is electrically connected to the resonator element 110 via the second internal terminal 125 and the second metal bump 132. The second external terminal 127 and the second connection terminal 32 are connected to each other via the second bonding member 42. The internal terminals 124 and 125 and the external terminals 126 and 127 are each formed by, for example, laminating a nickel layer and a gold layer in this order from the base 121 side.

The seam ring 128 is provided on the base 121. The seam ring 128 is provided between the base 121 and the lid 129. The seam ring 128 surrounds the recessed portion 122 formed in the base 121 in plan view. The seam ring 128 seam-welds the base 121 and the lid 129 together. The bonding between the base 121 and the lid 129 is not particularly limited, and may be performed using an adhesive.

As illustrated in FIG. 2, the lid 129 is provided on the seam ring 128. The lid 129 seals the opening of the recessed portion 122. The lid 129 has, for example, a plate shape. The lid 129 is made of, for example, metal such as Kovar, silicon, or the like.

The first metal bump 130 is provided between the first internal terminal 124 and the first terminal 114 of the resonator element 110. The second metal bump 132 is provided between the second internal terminal 125 and the second terminal 115 of the resonator element 110. The resonator element 110 is bonded to the internal terminals 124 and 125 via the metal bumps 130 and 132. In the example illustrated in FIG. 3, the shape of each of the metal bumps 130 and 132 is circular. The material of the metal bumps 130 and 132 is, for example, gold.

Note that a conductive adhesive such as silver paste may be provided instead of the metal bumps 130 and 132 and the resonator element 110 may be bonded to the internal terminals 124 and 125 via the conductive adhesive.

The first mounting terminal 80 illustrated in FIG. 1 is electrically connected to the first excitation electrode 112 via the integrated circuit portion 70, the first through electrode 20, the first connection terminal 30, the first bonding member 40, the first external terminal 126, the first internal terminal 124, the first metal bump 130, the first terminal 114, and the first wiring 116. The second mounting terminal 82 is electrically connected to the second excitation electrode 113 via the integrated circuit portion 70, the second through electrode 22, the second connection terminal 32, the second bonding member 42, the second external terminal 127, the second internal terminal 125, the second metal bump 132, the second terminal 115, and the second wiring 117.

### 1.3. Effects

The resonator device 100 includes the semiconductor substrate 10 having the first surface 12 and the second surface 14 being opposite to each other, the resonator 50 that is bonded to the first surface 12 and includes the resonator element 110 and the container 120 housing the resonator element 110, the integrated circuit portion 70 that is formed on the second surface 14 and includes the oscillation circuit electrically connected to the resonator element 110, and the first mounting terminal 80 connected to the integrated circuit portion 70.

Therefore, in the resonator device 100, since the first mounting terminal 80 and the integrated circuit portion 70 can be connected to each other without using a through electrode, it is possible to reduce jitter and to have favorable jitter characteristics. For example, the power supply and the output of the integrated circuit portion 70 can be obtained without using the through electrode. Further, in the resonator device 100, since the integrated circuit portion 70 is located outside the container 120, it is possible to reduce the size and the height of the container 120.

In the resonator device 100, the area of the semiconductor substrate 10 is larger than the area of the resonator 50 in plan view. Therefore, in the resonator device 100, it is possible to increase the size of the integrated circuit portion 70 compared to a case where the area of the semiconductor substrate is equal to or smaller than the area of the resonator. Thus, many circuits can be fabricated in the integrated circuit portion 70.

The resonator device 100 includes the first connection terminal 30 provided on the first surface 12, the container 120 includes the first external terminal 126 electrically connected to the resonator element 110 on the outer shell surface 123 facing the first surface 12, and the first external terminal 126 and the first connection terminal 30 are connected to each other via the first bonding member 40. Therefore, in the resonator device 100, the resonator 50 and the semiconductor substrate 10 can be electrically and mechanically firmly bonded to each other.

The resonator device 100 includes the resin material 60 with which at least a space between the first surface 12 and the outer shell surface 123 is filled. Therefore, in the resonator device 100, the bonding strength between the resonator 50 and the semiconductor substrate 10 can be improved.

In the resonator device 100, the container 120 may include the base 121 made of ceramic and the lid 129 made of metal. Therefore, the resonator device 100 can include the resonator 50 having excellent impact resistance and insulation properties. Thus, the durability and the reliability of the resonance characteristics can be improved.

In the resonator device 100, the container 120 may include the base 121 made of silicon and the lid 129 made of silicon. Therefore, in the resonator device 100, it is possible to reduce the difference in the thermal expansion coefficient between the container 120 and the semiconductor substrate 10. Thus, the bonding strength between the resonator 50 and the semiconductor substrate 10 can be maintained even in a high-temperature environment.

### 2. Method for Manufacturing Resonator Device

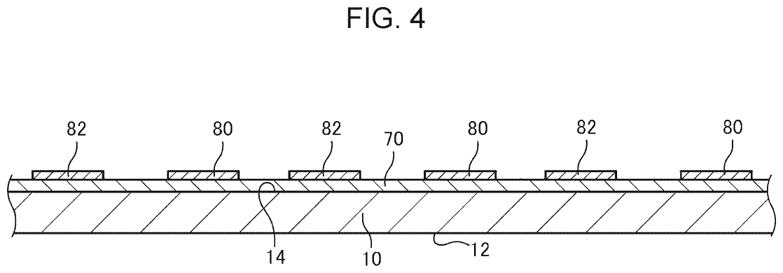

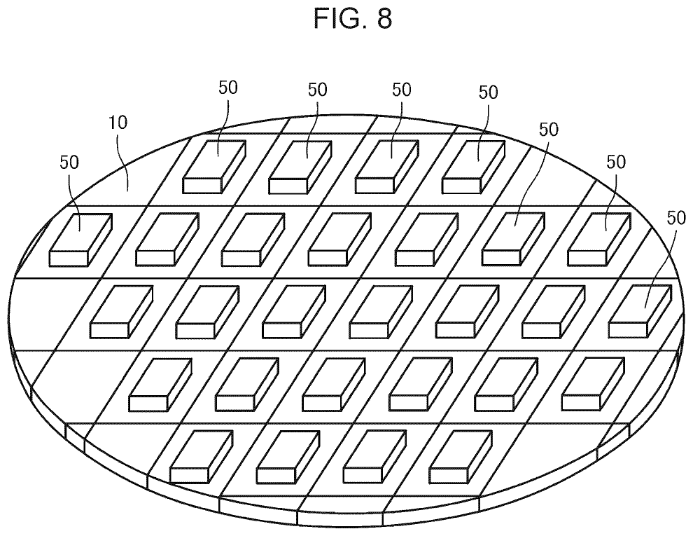

Next, a method for manufacturing resonator devices 100 according to the present embodiment will be described with reference to the drawings. FIGS. 4 to 7 are sectional views schematically illustrating manufacturing processes of the resonator devices 100 according to the present embodiment. FIG. 8 is a perspective view schematically illustrating a manufacturing process of the resonator devices 100 according to the present embodiment. For convenience, members other than the semiconductor substrate 10 and resonators 50 are not illustrated in FIG. 8.

As illustrated in FIG. 4, the integrated circuit portion 70 and the mounting terminals 80 and 82 are formed on the second surface 14 of the semiconductor substrate 10 which is a silicon wafer. The semiconductor substrate 10 is, for example, a silicon wafer. The integrated circuit portion 70 and the mounting terminals 80 and 82 are formed using a semiconductor process.

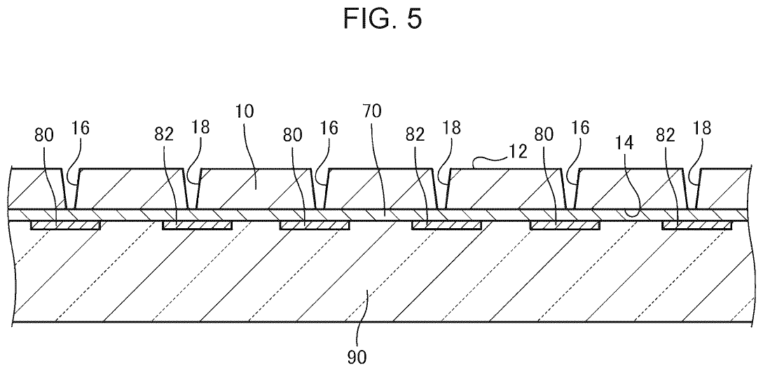

As illustrated in FIG. 5, a support substrate 90 is attached to the integrated circuit portion 70 and the mounting terminals 80 and 82. The support substrate 90 is, for example, a glass substrate. The support substrate 90 protects the integrated circuit portion 70 and the mounting terminals 80 and 82. Note that before the support substrate 90 is attached, the semiconductor substrate 10 may be thinned by grinding.

Next, the through holes 16 and 18 are formed in the semiconductor substrate 10 from the first surface 12 of the semiconductor substrate 10. The through holes 16 and 18 are formed by, for example, patterning by photolithography and etching.

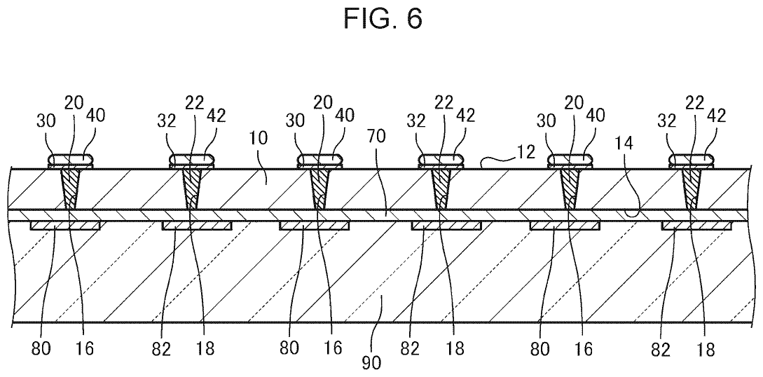

As illustrated in FIG. 6, the through electrodes 20 and 22 are formed in the through holes 16 and 18, respectively. Next, the connection terminals 30 and 32 are formed on the through electrodes 20 and 22, respectively. Next, the bonding members 40 and 42 are formed on the connection terminals 30 and 32, respectively. The through electrodes 20 and 22, the connection terminals 30 and 32, and the bonding members 40 and 42 are formed by, for example, a sputtering method, a vacuum vapor deposition method, a chemical vapor deposition (CVD) method, or a plating method.

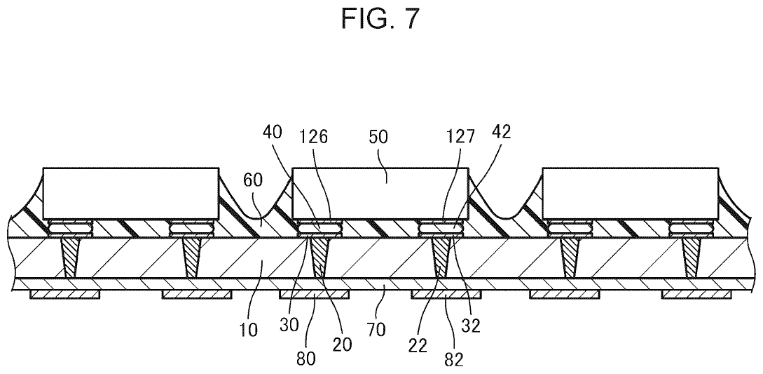

As illustrated in FIGS. 7 and 8, the resonators 50 are bonded to the semiconductor substrate 10. Specifically, each of the resonators 50 is bonded to the semiconductor substrate 10 via the bonding members 40 and 42 and the connection terminals 30 and 32.

As illustrated in FIG. 7, the resin material 60 is formed so as to fill the space between the semiconductor substrate 10 and the resonators 50. The resin material 60 is formed by, for example, a spin coating method or a CVD method. Next, the support substrate 90 is peeled off. After the support substrate 90 is peeled off, the mounting terminals 80 and 82 which are exposed may be subjected to plating.

As illustrated in FIGS. 1 and 8, the semiconductor substrate 10, which is a silicon wafer, is diced into individual pieces. For convenience, cutting lines for dicing are illustrated in FIG. 8.

Through the processes described above, the resonator device 100 can be manufactured. In the method for manufacturing the resonator device 100, a plurality of resonator devices 100 can be manufactured, and the resonator devices 100 can be efficiently mass-produced.

### 3. Modifications of Resonator Device

### 3.1. First Modification

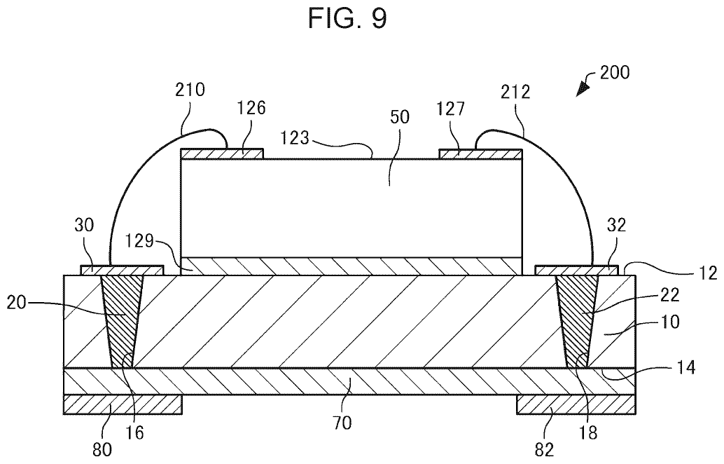

Next, a resonator device according to a first modification of the present embodiment will be described with reference to the drawings. FIG. 9 is a sectional view schematically illustrating a resonator device 200 according to the first modification of the present embodiment.

Hereinafter, in the resonator device 200 according to the first modification of the present embodiment, differences from the example of the resonator device 100 according to the present embodiment described above will be described, and the description of the same points will be simplified or omitted. The same applies to a resonator device according to a second modification of the present embodiment described later.

In the resonator device 100 described above, as illustrated in FIG. 1, the external terminals 126 and 127 of the resonator 50 are provided on the semiconductor substrate 10 side.

On the other hand, in the resonator device 200, as illustrated in FIG. 9, external terminals 126 and 127 are provided on the side opposite to the semiconductor substrate 10. An outer shell surface 123 on which the external terminals 126 and 127 are provided is a surface opposite to a surface facing a first surface 12.

A resonator 50 is mounted on the semiconductor substrate 10 with a lid 129 facing the semiconductor substrate 10. In plan view, the resonator 50 does not overlap through electrodes 20 and 22 and connection terminals 30 and 32.

The resonator device 200 includes, for example, a first conductive wire 210 and a second conductive wire 212. The first conductive wire 210 connects the first external terminal 126 to the first connection terminal 30. The second conductive wire 212 connects the second external terminal 127 to the second connection terminal 32. The material of the conductive wires 210 and 212 is, for example, gold or copper. The external terminals 126 and 127 are exposed. For example, the resonator device 200 does not include a resin material 60.

In the resonator device 200, a container 120 has the first external terminal 126 electrically connected to a resonator element 110 on the outer shell surface 123 opposite to the surface facing the first surface 12, and the first external terminal 126 and the first connection terminal 30 are connected to each other via the first conductive wire 210. Therefore, even after the resonator 50 is mounted on the semiconductor substrate 10 in the resonator device 200, the resonator element 110 can be inspected using the first external terminal 126.

### 3.2. Second Modification

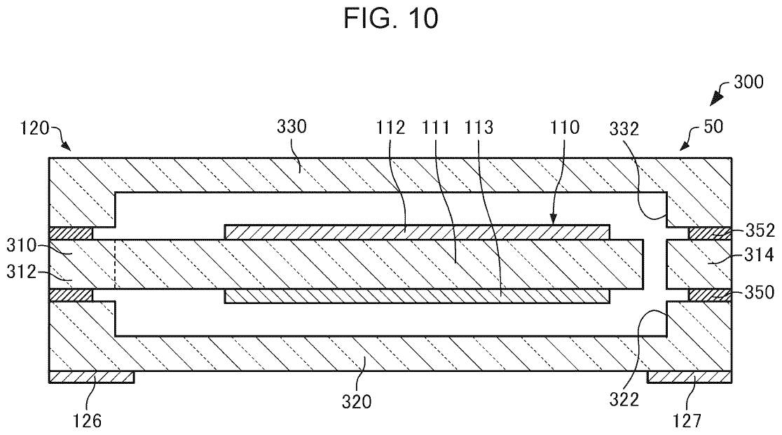

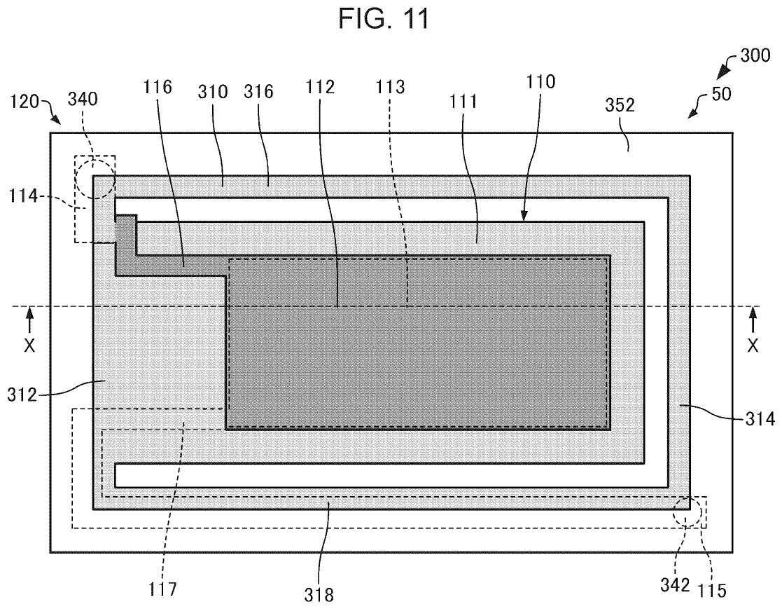

Next, a resonator device according to a second modification of the present embodiment will be described with reference to the drawings. FIG. 10 is a sectional view schematically illustrating a resonator 50 of a resonator device 300 according to the second modification of the present embodiment. FIG. 11 is a plan view schematically illustrating the resonator 50 of the resonator device 300 according to the second modification of the present embodiment. FIG. 10 is a sectional view taken along line X-X in FIG. 11.

In the resonator device 100 described above, as illustrated in FIG. 2, the container 120 has a configuration in which the recessed portion 122 is formed in the base 121 and the opening of the recessed portion 122 is sealed by the lid 129.

In contrast, in the resonator device 300, as illustrated in FIGS. 10 and 11, a container 120 includes a frame portion 310, a first sealing material 320, and a second sealing material 330. For convenience, the second sealing material 330 is not illustrated in FIG. 11.

The frame portion 310 is connected to a vibrating substrate 111. The frame portion 310 is integrally formed with the vibrating substrate 111. The frame portion 310 and the vibrating substrate 111 are made of, for example, quartz crystal.

As illustrated in FIG. 11, the frame portion 310 surrounds the vibrating substrate 111 in plan view. The frame portion 310 includes, for example, a first beam 312, a second beam 314, a third beam 316, and a fourth beam 318. The first beam 312 and the second beam 314 extend in a first direction in plan view. The third beam 316 and the fourth beam 318 extend in a second direction orthogonal to the first direction in plan view. The third beam 316 is connected to the beams 312 and 314. The fourth beam 318 is connected to the beams 312 and 314. The vibrating substrate 111 extends from the first beam 312 toward the second beam 314 side.

A first terminal 114 of a resonator element 110 is provided, for example, at a position overlapping a connection portion between the first beam 312 and the third beam 316 in plan view. The first terminal 114 is electrically connected to a first external terminal 126 through a first via 340.

A second terminal 115 of the resonator element 110 is provided, for example, at a position overlapping a connection portion between the second beam 314 and the fourth beam 318 in plan view. The second terminal 115 is electrically connected to a second external terminal 127 through a second via 342.

As illustrated in FIG. 10, the first sealing material 320 is bonded to the frame portion 310 via a first bonding material 350. The first sealing material 320 is provided on one surface side of the vibrating substrate 111. In the illustrated example, the first sealing material 320 is provided below the vibrating substrate 111. External terminals 126 and 127 are provided on an outer bottom surface of the first sealing material 320. A first recessed portion 322 is formed in the first sealing material 320 on the resonator element 110 side. The first recessed portion 322 can prevent the resonator element 110 from coming into contact with the first sealing material 320.

The second sealing material 330 is bonded to the frame portion 310 via a second bonding material 352. The second sealing material 330 is provided on the other surface side of the vibrating substrate 111. In the illustrated example, the second sealing material 330 is provided above the vibrating substrate 111. The resonator element 110 is provided between the first sealing material 320 and the second sealing material 330. A second recessed portion 332 is formed in the second sealing material 330 on the resonator element 110 side. The second recessed portion 332 can prevent the resonator element 110 from coming into contact with the second sealing material 330. The sealing materials 320 and 330 seal the resonator element 110. The sealing materials 320 and 330 are made of, for example, quartz crystal.

In the resonator device 300, the resonator element 110 includes the vibrating substrate 111 and excitation electrodes 112 and 113 that apply a voltage to the vibrating substrate 111, the container 120 includes the frame portion 310 that is integrally formed with the vibrating substrate 111 and surrounds the vibrating substrate 111 in plan view, the first sealing material 320 bonded to the frame portion 310 and provided on the one surface side of the vibrating substrate 111, and the second sealing material 330 bonded to the frame portion 310 and provided on the other surface side of the vibrating substrate 111, and the first sealing material 320 and the second sealing material 330 seal the resonator element 110. Therefore, in the resonator device 300, for example, the resonator element 110 does not need to be bonded to the container 120 using a metal bump or the like, and thus it is possible to achieve a reduction in thickness.

In the resonator device 300, the vibrating substrate 111, the frame portion 310, the first sealing material 320, and the second sealing material 330 are made of quartz crystal. Therefore, in the resonator device 300, it is possible to further reduce the thickness and to improve the stability of the frequency.

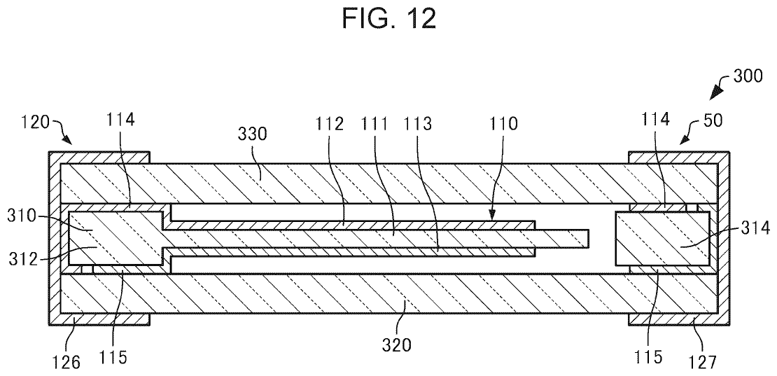

In the resonator device 300, as illustrated in FIG. 12, the terminals 114 and 115 may be provided on the first beam 312, and the terminals 114 and 115 may be provided on the second beam 314. The first terminal 114 provided on the first beam 312 is connected to the first external terminal 126. The second terminal 115 provided on the first beam 312 is spaced apart from the first external terminal 126. The second terminal 115 provided on the second beam 314 is connected to the second external terminal 127. The first terminal 114 provided on the second beam 314 is spaced apart from the second external terminal 127. In the illustrated example, the first external terminal 126 is provided on the front and rear surfaces and a side surface of the container 120. The second external terminal 127 is provided on the front and rear surfaces and a side surface of the container 120.

The above-described embodiments and modifications are merely examples, and the present disclosure is not limited thereto. For example, each of the embodiments and each of the modifications may be combined as appropriate.

The present disclosure includes configurations substantially the same as the configurations described in the embodiments, for example, configurations having the same function, method, and result, or configurations having the same purpose and effect. Further, the present disclosure includes configurations in which non-essential portions of the configurations described in the embodiments are replaced. In addition, the present disclosure includes configurations that achieve the same effects as the configurations described in the embodiments or configurations capable of achieving the same object. Furthermore, the present disclosure includes configurations in which a known technique is added to the configurations described in the embodiments.

The following contents are derived from the above-described embodiments and modifications.

According to an aspect of the present disclosure, there is provided a resonator device including a semiconductor substrate having a first surface and a second surface being opposite to each other, a resonator that is bonded to the first surface and includes a resonator element and a container housing the resonator element, an integrated circuit portion that is formed on the second surface and includes an oscillation circuit electrically connected to the resonator element, and mounting terminals connected to the integrated circuit portion.

According to this resonator device, it is possible to have favorable jitter characteristics.

In the resonator device according to an aspect of the present disclosure, an area of the semiconductor substrate may be larger than an area of the resonator in plan view.

According to this resonator device, it is possible to increase the size of the integrated circuit portion.

In an aspect of the resonator device, the resonator device may include connection terminals provided on the first surface, the container may include external terminals electrically connected to the resonator element on a surface facing the first surface, and each of the external terminals may be connected to a corresponding one of the connection terminals via a corresponding one of bonding members.

According to this resonator device, the resonator and the semiconductor substrate can be electrically and mechanically firmly bonded to each other.

In an aspect of the resonator device, the resonator device may include a resin material with which at least a space between the first surface and the surface facing the first surface is filled.

According to this resonator device, it is possible to improve the bonding strength between the resonator and the semiconductor substrate.

In an aspect of the resonator device, the resonator device may include connection terminals provided on the first surface, the container may include external terminals electrically connected to the resonator element on a surface opposite to a surface facing the first surface, and each of the external terminals may be connected to a corresponding one of the connection terminals via a corresponding one of conductive wires.

According to this resonator device, even after the resonator is mounted on the semiconductor substrate, the resonator element can be inspected using the external terminals.

In an aspect of the resonator device, the container may include a base made of ceramic and a lid made of metal.

According to this resonator device, it is possible to include the resonator having excellent impact resistance and insulation properties.

In an aspect of the resonator device, the container may have a base made of silicon and a lid made of silicon.

According to this resonator device, it is possible to reduce the difference in the thermal expansion coefficient between the container and the semiconductor substrate.

In an aspect of the resonator device, the resonator element may include a vibrating substrate and excitation electrodes that apply a voltage to the vibrating substrate, the container may include a frame portion that is integrally formed with the vibrating substrate and surrounds the vibrating substrate in plan view, a first sealing material bonded to the frame portion and provided on one surface side of the vibrating substrate, and a second sealing material bonded to the frame portion and provided on the other surface side of the vibrating substrate, and the first sealing material and the second sealing material may seal the resonator element.

According to this resonator device, it is possible to achieve a reduction in thickness.

In an aspect of the resonator device, the vibrating substrate, the frame portion, the first sealing material, and the second sealing material may be made of quartz crystal.

According to this resonator device, it is possible to improve the stability of the frequency.

What is claimed is:

1. A resonator device comprising:
a semiconductor substrate having a first surface and a second surface being opposite to each other;
a resonator that is bonded to the first surface and includes a resonator element and a container housing the resonator element;
an integrated circuit portion that is formed on the second surface and includes an oscillation circuit electrically connected to the resonator element; and
mounting terminals connected to the integrated circuit portion.

2. The resonator device according to claim 1, wherein
an area of the semiconductor substrate is larger than an area of the resonator in plan view.

3. The resonator device according to claim 1, further comprising
connection terminals provided on the first surface, wherein
the container includes external terminals electrically connected to the resonator element on a surface facing the first surface, and
each of the external terminals is connected to a corresponding one of the connection terminals via a corresponding one of bonding members.

4. The resonator device according to claim 3, further comprising
a resin material with which at least a space between the first surface and the surface facing the first surface is filled.

5. The resonator device according to claim 2, further comprising
connection terminals provided on the first surface, wherein
the container includes external terminals electrically connected to the resonator element on a surface opposite to a surface facing the first surface, and
each of the external terminals is connected to a corresponding one of the connection terminals via a corresponding one of conductive wires.

6. The resonator device according to claim 1, wherein
the container includes
a base made of ceramic, and
a lid made of metal.

7. The resonator device according to claim 1, wherein
the container includes
a base made of silicon, and
a lid made of silicon.

8. The resonator device according to claim 1, wherein
the resonator element includes a vibrating substrate and excitation electrodes that apply a voltage to the vibrating substrate,
the container includes
a frame portion that is integrally formed with the vibrating substrate and surrounds the vibrating substrate in plan view,
a first sealing material bonded to the frame portion and provided on one surface side of the vibrating substrate, and
a second sealing material bonded to the frame portion and provided on an other surface side of the vibrating substrate, and
the first sealing material and the second sealing material seal the resonator element.

9. The resonator device according to claim 8, wherein
the vibrating substrate, the frame portion, the first sealing material, and the second sealing material are made of quartz crystal.
